(19) United States
(12) Patent Application Publication
(10) Pub. No.: US 2024/0350986 A1
(43) Pub. Date: Oct. 24, 2024

(54) CHEMICAL PRECURSOR BUBBLER ASSEMBLY WITH ROUTING STRUCTURE

(71) Applicant: William L. KIMMERLE, Hudson, OH (US)

(72) Inventor: William L. KIMMERLE, Hudson, OH (US)

(21) Appl. No.: 18/762,146

(22) Filed: Jul. 2, 2024

Related U.S. Application Data
(63) Continuation of application No. 17/000,933, filed on Aug. 24, 2020, now abandoned.

(51) Int. Cl. B01F 23/232; B01F 23/30; C23C 16/448

(52) U.S. Cl. CPC B01F 23/232312; B01F 23/30; C23C 16/4481

(57) ABSTRACT

A bubbler apparatus may include a container, a lid, a sealing member and at least one routing member. As the lid is tightened to the container and the sealing member is compressed, the routing member(s) does not contact the inside bottom surface of the container. Instead, there is a small gap between the routing member and the bottom surface of the container. The routing member may compress the substance in the container that the gas is saturated with or may slice through the substance.

### I. BACKGROUND

This application is a continuation of U.S. patent application Ser. No. 17/000,933 filed Aug. 24, 2020, the contents of which are incorporated herein by reference.

### A. Field of the Invention

This invention generally relates to apparatuses and methods for generating a carrier gas stream containing a desired compound and more specifically to apparatuses and methods related to a chemical precursor bubbler design and operation.

### B. Description of Related Art

Apparatuses and systems for generating carrier gas streams containing a desired compound, under controlled environmental conditions, are used in a variety of industries. For example, “bubblers” are often used in the electronics fabrication industry, particularly when manufacturing semiconductors, integrated circuits, computer chips and LEDs. A carrier gas saturated with the desired compound may be delivered to processing equipment that provides for deposition of the compound to form layers and/or films, for example. The carrier gas may be saturated with the desired compound by “bubbling” it through a container comprising a solid or liquid precursor that comprises the desired compound.

FIG. 1 illustrates a bubbler apparatus 1 including a container 2, having an inside bottom surface 16, and a removable top or lid 3. Fasteners 4 may be received in holes 5, 6 in the top 3 and container 2 to secure the top 3 to the container 2. A sealing member 7, such as a gasket, may be positioned between the top 3 and the container 2 to form a seal between the top 3 and the container 2 during operation of the bubbler apparatus. The apparatus may include an inlet 8 through which a gas stream enters the bubbler and an outlet 9 through which the gas stream exits the bubbler.

In some applications, as illustrated in FIG. 2, it is desirable to insert (and remove when necessary) a routing structure 10 within a bubbler container 11 as indicated with reference 12. The routing structure 10, when installed in the container 11, routes the gas as it moves through the bubbler (one example of the gas route is shown with arrows 13 from IN to OUT). The routing structure 10 may include routing members 14 that extend, once inserted within the container 11, laterally and vertically. Openings 15 may be provided in the routing members 14 to create flow passages for the gas.

Know bubbler apparatuses generally work well for their intended purposes. One known problem, however, with reference to FIGS. 1 and 2, relates to the use of routing structures 10 that extend vertically from the top 3 to the inside bottom surface 16 of the container 2, 11. Specifically, in order to obtain a sufficient seal between the top 3 and the container 2, it is necessary to provide sufficient force to compress the sealing member 7 by, for example, properly tightening the fasteners 4. The application of this tightening force, however, applies a force to the top of the routing members 14 (from the top 3) causing the bottom surfaces of the routing members 14 to move toward the inside bottom surface 16 of the container 2, 11. If the routing member 14 is too tall (relative to the height of the container), this force causes the bottom surfaces of the routing members 14 to contact the inside bottom surface 16 of the container-preventing a good seal between the top and the container.

### II. SUMMARY

According to some embodiments of this invention, a method for a bubbler apparatus may include the steps of: A) providing a bubbler apparatus including: 1) a container having: a) a top and a bottom defining an inside bottom surface; and b) a height H1 from the top to the inside bottom surface; 2) a lid; 3) a scaling member; 4) an inlet opening; 5) an outlet opening; and 6) a gas routing structure including a first routing member; B) providing the bubbler apparatus to be operable to perform the following steps: 1) placing a substance within the container; 2) placing the first routing member within the container; 3) placing the scaling member on the top of the container; 4) placing the lid on the sealing member; 5) tightening the lid to the sealing member thereby compressing the sealing member; 6) providing the first routing member with a vertical height H2 within the container between the top of the container and a distal end of the first routing member; 7) providing H2 to be less than H1 thereby forming a gap between the distal end of the first routing member and the inside bottom surface of the container; and 8) moving a gas stream: into the container through the inlet opening; into contact with the substance to saturate the gas with the substance; into contact with the first routing member to rout the gas within the container; and out of the container through the outlet opening. Step B6 may occur after step B5.

According to some embodiments of this invention, a bubbler apparatus may include: a container having: 1) a top and a bottom defining an inside bottom surface; and 2) a height H1 from the top to the inside bottom surface; a lid; a sealing member; an inlet opening; an outlet opening; and gas routing structure including a first routing member. The bubbler apparatus may be operable to: 1) place a substance within the container; 2) place the first routing member within the container; 3) place the sealing member on the top of the container; 4) place the lid on the sealing member; 5) tighten the lid to the sealing member thereby compressing the sealing member; 6) provide the first routing member with a vertical height H2 within the container between the top of the container and a distal end of the first routing member after the lid has been tightened; 7) provide H2 to be less than H1 thereby forming a gap between the distal end of the first routing member and the inside bottom surface of the container; and 8) move a gas stream: into the container through the inlet opening; into contact with the substance to saturate the gas with the substance; into contact with the first routing member to rout the gas within the container; and out of the container through the outlet opening.

According to some embodiments of this invention, a method of operating a bubbler apparatus may include the steps of: A) providing a bubbler apparatus including: 1) a container having: a) a top and a bottom defining an inside bottom surface; and b) a height H1 from the top to the inside bottom surface; 2) a lid; 3) a sealing member; 4) an inlet opening; 5) an outlet opening; and 6) a gas routing structure including a first routing member; B) placing a substance within the container; C) placing the first routing member within the container; D) placing the sealing member on the top of the container; E) placing the lid on the sealing member; F) tightening the lid to the sealing member thereby compressing the sealing member; G) providing the first routing member with a vertical height H2 within the container between the top of the container and a distal end of the first routing member; H) providing H2 to be less than H1 thereby forming a gap between the distal end of the first routing member and the inside bottom surface of the container; and I) moving a gas stream: into the container through the inlet opening; into contact with the substance to saturate the gas with the substance; into contact with the first routing member to rout the gas within the container; and out of the container through the outlet opening. Step G may occur after step F.

According to some embodiments of this invention, the gap between the distal end of the routing member and the bottom surface of the container is between 0.10 inches and 0.01 inches.

According to some embodiments of this invention, the gap between the distal end of the routing member and the bottom surface of the container is about 0.03 inches.

According to some embodiments of this invention, the distal end of the routing member is flat and compresses the substance in the container when the lid is tightened to the sealing member.

According to some embodiments of this invention, the distal end of the routing member is pointed and slices through the substance in the container when the lid is tightened to the sealing member.

According to some embodiments of this invention, multiple routing members can be used.

### III. BRIEF DESCRIPTION OF THE DRAWINGS

The invention may take physical form in certain parts and arrangement of parts, embodiments of which will be described in detail in this specification and illustrated in the accompanying drawings which form a part hereof and wherein:

FIG. 1 is a top perspective view of a known bubbler apparatus.

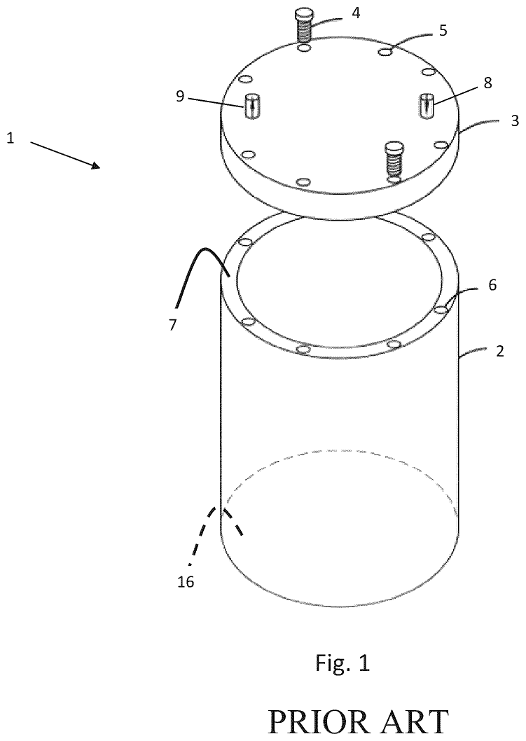

FIG. 2 is a top perspective view of a known bubbler apparatus.

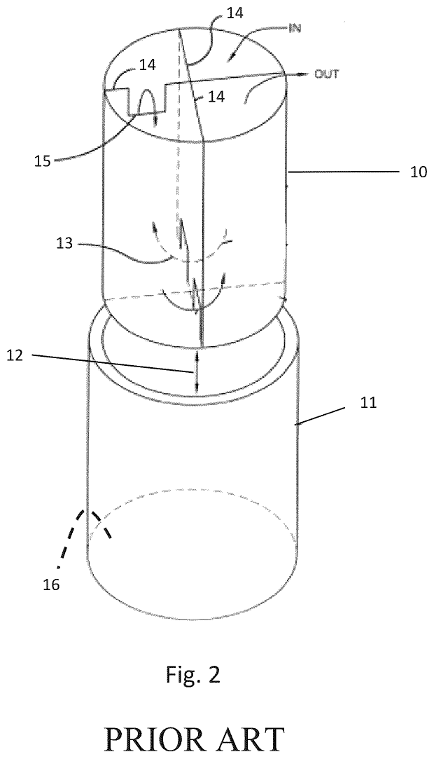

FIG. 3 is a top perspective view of a bubbler apparatus according to some embodiments of this invention.

FIG. 4 is a side perspective view of the bubbler apparatus shown in FIG. 3 but at a different angle and showing the bubbler apparatus being assembled.

FIG. 5 is a sectional view of the bubbler apparatus shown in FIG. 3 with the valves and piping removed for clarity.

FIG. 6 is a view along line 6-6 in FIG. 5.

FIG. 7 is a close-up side view showing the distal end of a routing member according to one embodiment of this invention.

FIG. 8 is a close-up side view showing the distal end of a routing member according to another embodiment of this invention.

### IV. DETAILED DESCRIPTION

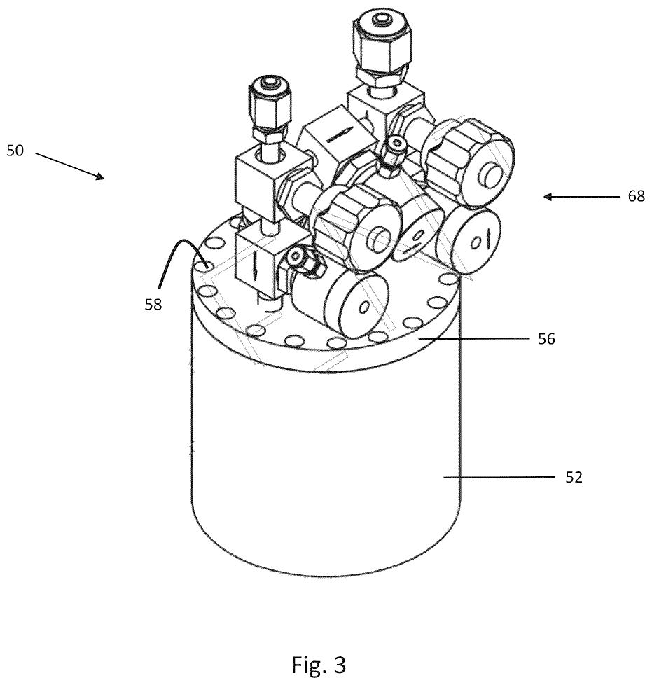

Referring now to the drawings wherein the showings are for purposes of illustrating embodiments of the invention only and not for purposes of limiting the same, and wherein like reference numerals are understood to refer to like components, FIG. 3-5 shows a bubbler apparatus 50 according to some embodiments of this invention. The bubbler apparatus 50 may include a container 52, having a bottom 55 defining an inside bottom surface 54, and a removable lid 56. Fasteners, not shown, may be received in holes 58, 60 in the lid 56 and container 52 to secure the lid 56 to the container 52. A sealing member 62, such as a gasket, may be positioned between the lid 56 and the container 52 to form a seal between the lid 56 and the container 52 during operation of the bubbler apparatus 50. The apparatus may include an inlet 64 through which a gas stream enters the bubbler and an outlet 66 through which the gas stream exits the bubbler. Valves and piping 68 may also be provided to operate the bubbler apparatus 50 as is well known to those of skill in the art.

With reference now to FIGS. 3-6, the bubbler apparatus 50 may include a routing structure 70 that routes the gas as it moves through the bubbler as described above and well known to those of skill in the art. The routing structure 70 may include one or more routing members 72 that extend, once inserted within the container 52, laterally and vertically. While the routing members 72 shown are planar in shape, it should be understood that any shape chosen with the sound judgment of a person of skill in the art may be used with this invention. It should also be understood that the number of routing members 72 used may be any chosen with the sound judgment of a person of skill in the art. Five are provided in the embodiment shown.

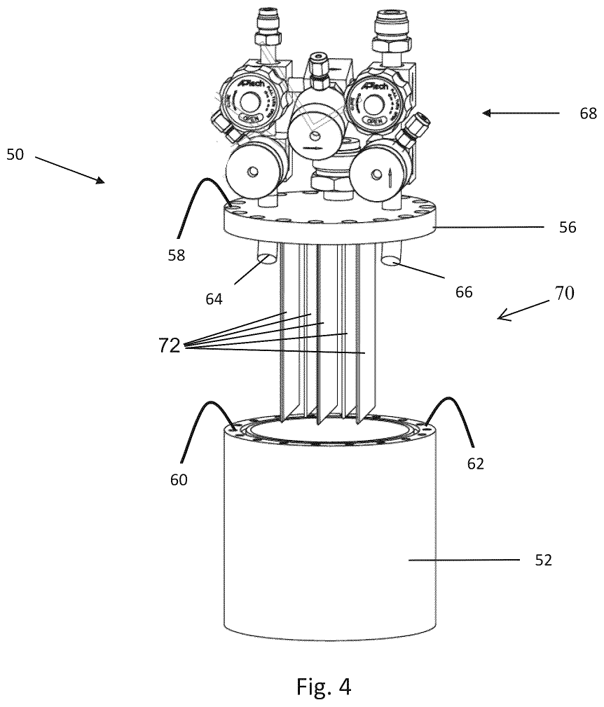

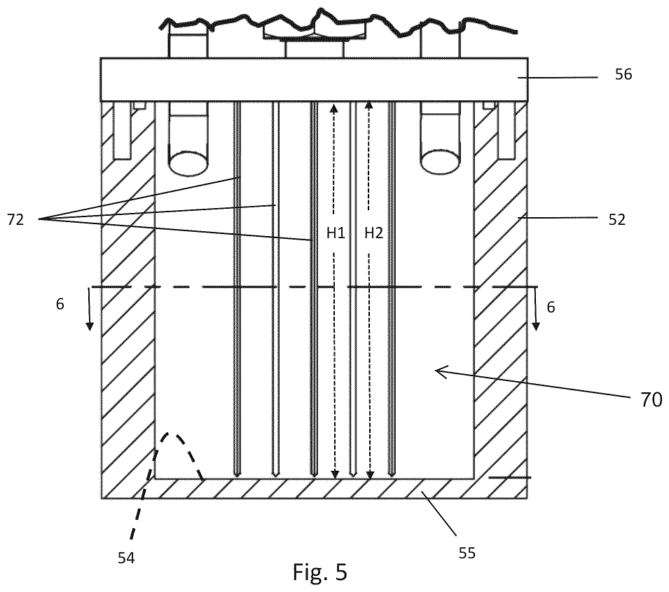

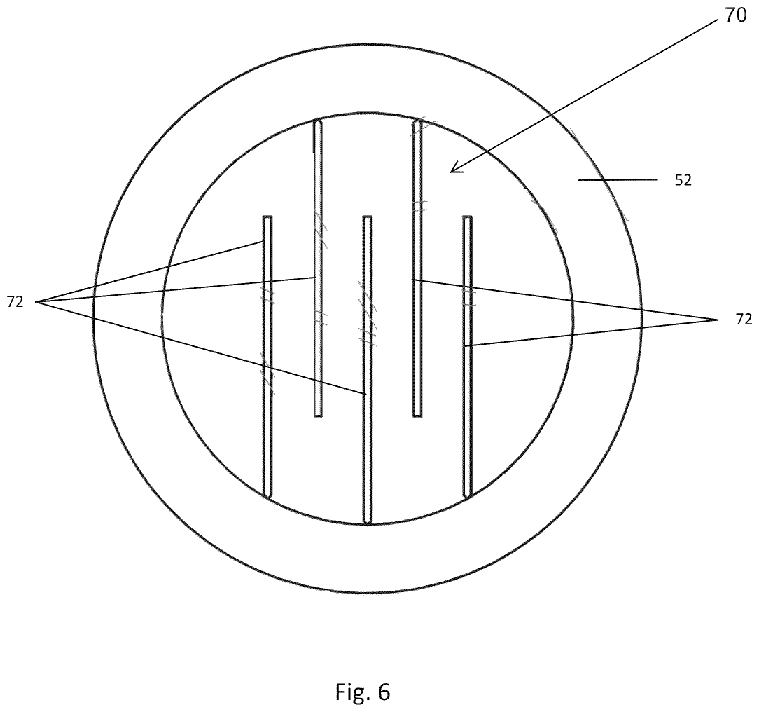

With reference now to FIGS. 4-6, the routing members 72 may be similarly shaped or may have differing shapes. The routing members 72 may be positioned within the container 52 in any manner chosen with the sound judgment of a person of skill in the art to achieve the desired flow characteristics for the gas as it passes through the bubbler. For the embodiment shown, see especially FIG. 6, three of the routing members 72 have sides near one side of the container 52 and the other two routing members 72 have sides near the opposite side of the container 52. As shown in FIG. 5, the container 52 may have a height H1 from the inside bottom surface 54 to the top of the container. At least one routing member 72 may have a height H2 from the bottom surface of the lid 56 to its distal end (away from the lid 56). For the embodiment shown, the routing members 72 are attached to the lid 56.

With reference now to FIGS. 4-8, the routing member 72 height H2 is smaller than the distance between the bottom surface of the lid 56 and the inside bottom surface 54 of the bottom 55 after the lid 56 is properly secured to the container 52 with the sealing member 62 properly sealed. This difference forms a gap 74 between the distal end of the routing member 72 and the inside bottom surface 54. Gap 74 may be any non-zero distance chosen with the sound judgment of a person of skill in the art. In one embodiment, the gap 74 is between 0.10 inches and 0.01 inches. In one specific embodiment, gap 74 is about 0.03 inches.

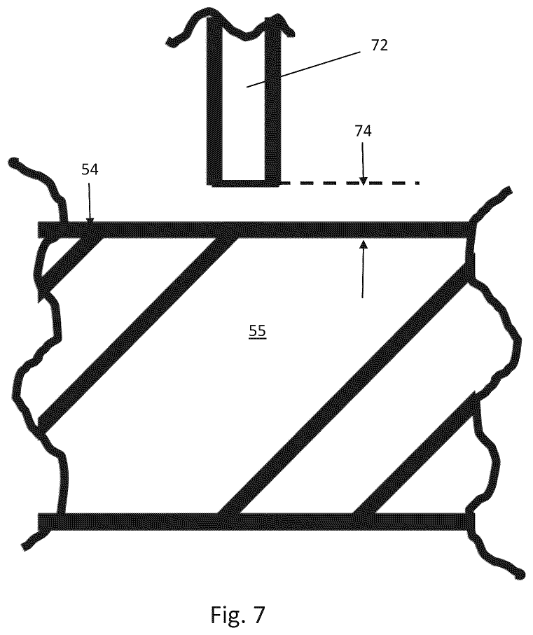

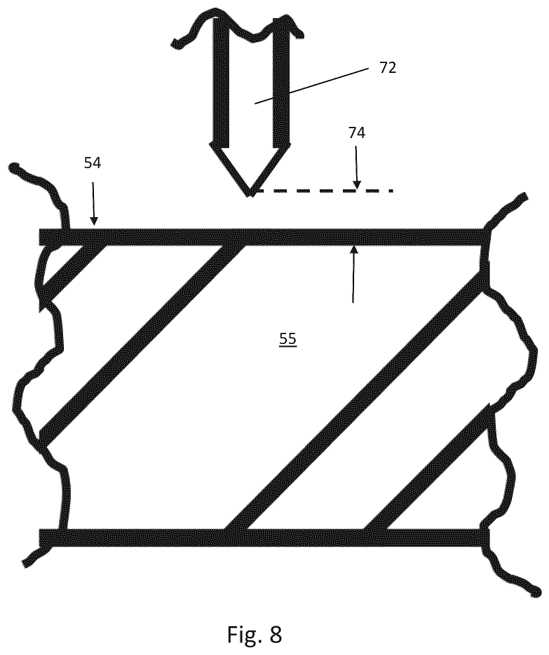

In use, when the lid 56 is properly attached to the container 52 (compressing the scaling member 62) and routing member(s) 72 is extended into the container, the distal end of the routing member(s) 72 does not contact the inside bottom surface 54 because of the gap 74. The distal end of the routing member(s) 74 may, however, contact the substance, such as a compound, within the container. For the embodiment shown in FIG. 7, the distal end of the routing member 72 is flat and thus compresses the substance within the container when inserted. For the embodiment shown in FIG. 8, the distal end of the routing member 72 is pointed and thus slices through the substance within the container when inserted. In both cases, the routing member(s) 72 provides the necessary seal with the inside bottom surface 54 of the bottom 55 without contacting the bottom surface 54.

A plurality of different embodiments of the invention is shown in the Figures of the application. Similar features are shown in the various embodiments of the invention. Similar features are structured similarly, operate similarly, and/or have the same function unless otherwise indicated by the drawings or this specification. Furthermore, particular features of one embodiment can replace corresponding features in another embodiment or can supplement other embodiments unless otherwise indicated by the drawings or this specification.

Numerous embodiments have been described herein. It will be apparent to those skilled in the art that the above methods and apparatuses may incorporate changes and modifications without departing from the general scope of this invention. It is intended to include all such modifications and alterations in so far as they come within the scope of the appended claims or the equivalents thereof. Further, the “invention” as that term is used in this document is what is claimed in the claims of this document. The right to claim elements and/or subcombinations that are disclosed herein as other inventions in other patent documents is hereby unconditionally reserved.

Having thus described the invention, it is now claimed:

I/We claim:

1. A method comprising the steps of:
A) providing a bubbler apparatus including:
1) a container having: a) a top and a bottom defining an inside bottom surface; and b) a height H1 from the top to the inside bottom surface;
2) a lid;
3) a sealing member;
4) an inlet opening;
5) an outlet opening; and
6) a gas routing structure including a first routing member having a distal end;
B) providing the bubbler apparatus to be operable to perform the following steps:
1) placing a substance within the container;
2) placing the first routing member within the container;
3) placing the sealing member on the top of the container;
4) placing the lid on the sealing member;
5) tightening the lid to the sealing member thereby compressing the sealing member and sealing the distal end of the first routing member to the inside bottom surface of the container;
6) providing the first routing member with a vertical height H2 within the container between the top of the container and the distal end of the first routing member;
7) providing H2 to be less than H1 thereby forming a gap between the distal end of the first routing member and the inside bottom surface of the container that is between 0.10 inches and 0.01 inches; and
8) moving a gas stream: into the container through the inlet opening; into contact with the substance to saturate the gas with the substance; into contact with the first routing member to rout the gas within the container; and out of the container through the outlet opening;
wherein: step B6 occurs after step B5.

2. The method of claim 1 wherein:
the gas routing structure is positioned between the inlet opening and the outlet opening.

3. The method of claim 1 wherein:
the gap is about 0.03 inches.

4. The method of claim 1 wherein:
the distal end of the first routing member is flat and compresses the substance when the lid is tightened to the sealing member.

5. The method of claim 1 wherein:
the distal end of the first routing member is pointed and slices through the substance when the lid is tightened to the sealing member.

6. The method of claim 1 wherein:
the first routing member: 1) is attached to the lid; 2) is planar in shape extending laterally and vertically when positioned within the container; and 3) has a side positioned near one side of the container when positioned within the container;
the gas routing structure includes a second routing member that: 1) is distinct from the first routing member; 2) is attached to the lid; 3) is planar in shape extending laterally and vertically when positioned within the container; 4) has a side positioned near the opposite side of the container when positioned within the container; and 5) has a distal end;
wherein the bubbler apparatus is operable to:
1) place the second routing member within the container so that the distal end of the second routing member is sealed to the inside bottom surface of the container;
2) provide the second routing member with a vertical height H3 within the container between the top of the container and the distal end of the second routing member after the lid has been tightened;
3) provide H3 to be less than H1 thereby forming a gap between the distal end of the second routing member and the inside bottom surface of the container that is between 0.10 inches and 0.01 inches; and
4) move a gas stream: into the container through the inlet opening; into contact with the substance to saturate the gas with the substance; into contact with the second routing member to rout the gas within the container; and out of the container through the outlet opening.

7. The method of claim 1 wherein:
one or more fasteners are operable to tighten the lid to the sealing member thereby compressing the sealing member.

8. A method comprising the steps of:
A) providing a bubbler apparatus including:
1) a container having: a) a top and a bottom defining an inside bottom surface; and b) a height H1 from the top to the inside bottom surface;
2) a lid;
3) a sealing member;
4) an inlet opening;
5) an outlet opening; and
6) a gas routing structure including a first routing member having a distal end;
B) placing a substance within the container;
C) placing the first routing member within the container;
D) placing the sealing member on the top of the container;
E) placing the lid on the sealing member;
F) tightening the lid to the sealing member thereby compressing the sealing member and sealing the distal end of the first routing member to the inside bottom surface of the container;
G) providing the first routing member with a vertical height H2 within the container between the top of the container and the distal end of the first routing member;
H) providing H2 to be less than H1 thereby forming a gap between the distal end of the first routing member and the inside bottom surface of the container that is between 0.10 inches and 0.01 inches; and
I) moving a gas stream: into the container through the inlet opening; into contact with the substance to saturate the gas with the substance; into contact with the first routing member to rout the gas within the container; and out of the container through the outlet opening;
wherein step G occurs after step F.

9. The method of claim 8 wherein step C comprises the step of:
positioning the gas routing structure between the inlet opening and the outlet opening.

10. The method of claim 8 wherein step H comprises the step of:
forming the gap to be about 0.03 inches.

11. The method of claim 8 wherein:
step A6 comprises the step of: providing the distal end of the first routing member to be flat; and
step F comprises the step of: tightening the lid to compress the substance with the distal end of the first routing member.

12. The method of claim 8 wherein:
step A6 comprises the step of: providing the distal end of the first routing member to be pointed; and
step F comprises the step of: tightening the lid to slice through the substance with the distal end of the first routing member.

13. The method of claim 8 wherein:
step A6 comprises the step of: providing one or more fasteners; and
step F comprises the step of: using the one or more fasteners to tighten the lid to the sealing member.
